(19) United States
(12) Patent Application Publication
(10) Pub. No.: US 2005/0074705 A1
(43) Pub. Date: Apr. 7, 2005

(54) Method of forming a resist pattern, method of forming a wiring pattern, method of fabricating a semiconductor device, electro-optic device, and electronic apparatus

(75) Inventor: Naoyuki Toyoda, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/902,147

(22) Filed: Jul. 30, 2004

(30) Foreign Application Priority Data
Aug. 8, 2003 (JP) 2003-290658

(51) Int. Cl. G03F 7/00

(52) U.S. Cl. 430/323; 430/311; 430/313; 430/322

(57) ABSTRACT

A method of forming a resist pattern with enhanced productivity is provided. While facing a process object with a resist layer including a resist material provided on a base member including a photothermal conversion layer to convert light energy into thermal energy, by irradiating a predetermined area of the base member with a light beam, the resist material corresponding to the predetermined area is transferred to the process object, thereby patterning the resist material on the process object.

### BACKGROUND

Exemplary aspects of the present invention relate to a method of patterning a resist film on a member to be processed to form a resist pattern, a method of forming a wiring pattern and a method of manufacturing a semiconductor device using the resist pattern, an electro-optic device, and an electronic apparatus.

The photolithography process is frequently used as a related art manufacturing method of devices having fine wiring patterns, such as semiconductor integrated circuits. Japanese Unexamined Patent Publication No. 6-347637 discloses a technology to form, using the photolithography process, banks (black matrixes) used to dispose droplets of functional fluid using the droplet ejection process.

### SUMMARY

In the photolithography process, a resist layer is formed by depositing the resist material on a process object. Then, the exposure process is executed on the resist layer. A further development process is executed, thereby providing a predetermined resist pattern. In this case, many processes are required, and accordingly the productivity is decreased.

Exemplary aspects of the present invention address the above and/or other situations and provide methods of forming a resist pattern with enhanced productivity. Further, exemplary aspects of the present invention provide a method of forming a wiring pattern using the resist pattern, a method of manufacturing a semiconductor device using the resist pattern, and an electro-optic device and an electronic apparatus equipped with the wiring pattern or the semiconductor device.

In order to address or solve the above and/or other problems, a resist pattern forming method according to an exemplary aspect of the present invention includes providing a resist layer including resist material on a base member including a photothermal conversion material to convert light energy into thermal energy, facing the resist layer with a process object, and irradiating a predetermined part of the base member with a light beam to transfer the resist material corresponding to the predetermined part to the process object, thereby patterning the resist material on the process object. According to an exemplary aspect of the present invention, since the base member includes photothermal conversion material, light energy of the irradiated light beam can efficiently be converted into thermal energy. And, by supplying the thermal energy to the resist material, a part of the resist material can be melted to be transferred to the process object. Therefore, by irradiating a predetermined region on the base member corresponding to the resist pattern to be formed, the resist material of the resist layer corresponding to the predetermined region can be transferred to the process object, thus forming a desired resist pattern on the process object. In addition, since in the exemplary aspect of the present invention, a desired resist pattern can be formed on the process object only by irradiating with light and any development processes in related art methods are not required, the productivity can be enhanced.

In the resist pattern forming process according to an exemplary aspect of the present invention, the base member, the resist layer, and the photothermal conversion layer can be provided independently from each other, or the photothermal conversion material can be dispersed in the base member, or the photothermal conversion material can be dispersed in the resist layer. Even by either of the above configurations, the light energy of the irradiated beam can be converted into thermal energy which is in turn provided to the resist layer.

In the configuration in which the base member, the resist layer, and the photothermal conversion layer, including the photothermal conversion material, are provided independently from each other, the photothermal conversion layer can be provided on the same side as the resist layer or the photothermal conversion layer can be provided on the opposite side to the resist layer. By either of the above configurations, the light energy of the irradiated laser beam can be converted into thermal energy which is in turn provided to the resist layer. Especially, by providing the photothermal conversion layer between the base member and the resist layer, the thermal energy generated by the photothermal conversion layer can effectively be provided to the resist layer adjacent to the photo thermal conversion layer.

The method of forming a resist pattern according to an exemplary aspect of the present invention, a configuration can be adopted in which a gas generation layer is provided between the base member and the resist layer, the gas generation layer including a gas generation material that generates gas in response to one of irradiation of a light beam and heat. Alternatively, a configuration in which the gas generation material that generates gas in response to one of irradiation of a light beam and heat is dispersed in the base member can be adopted. Since the gas generated by the gas generation material gives energy to separate the base member from the resist layer, the resist layer can efficiently be transferred to the process object.

In the resist pattern forming method of an exemplary aspect of the present invention, the light beam is a laser beam, the light having a suitable wavelength to the photothermal conversion materials may be irradiated. Thus, the light energy of the light irradiating the photothermal conversion material can efficiently be converted into the thermal energy.

In the resist pattern forming method of an exemplary aspect of the present invention, a configuration of irradiating the base member with the light beam passing through a mask having a predetermined pattern can be adopted. Thus, a resist pattern finer than the size of the irradiated light beam can be formed. In contrast, a configuration in which the base member and process object are moved relative to the light beam during the irradiation by the light beam can also be adopted. The resist pattern can be drawn by moving the irradiating beam relative to the base member and the process object, and, in this case, the mask forming process can be omitted.

In the resist pattern forming method of an aspect of the present invention, a configuration in which the irradiation is executed while the resist layer of the base member and the process object are adhered to each other can be adopted. Thus, the resist material can efficiently be transferred to the process object from the base member. In this case, the resist layer and the process object can be adhered by depressurizing the space between the resist layer and the process object after facing the resist layer and the process object to each other. Further, by releasing the depressurized condition after the transfer process has been completed, the base member can be separated from the process object.

The method of forming a resist pattern according to an exemplary aspect of the present invention, may include providing the process object with an etching object layer, and etching the etching object layer after irradiating to form a pattern thereon corresponding to a pattern of the resist layer. Thus, using the resist pattern having etching resistance, the pattern can be formed on the etching object layer on the process object.

In the wiring pattern forming method of an exemplary aspect of the present invention, the bank is formed by using the resist pattern formed on the process object by the resist pattern forming method described above. The wiring pattern is made by disposing the droplets of the wiring pattern forming material between the banks. According to an exemplary aspect of the present invention, using the droplet ejection method, the fine wiring pattern can efficiently be formed while reducing the waste of the material.

Note that, the bank is a partitioning member to define a predetermined region on the process object, and other than using the banks to realize accuracy in the width of the patterns, the banks are also used to partition the adjacent pixels in the color filters or the organic EL displays.

A method of fabricating a semiconductor device according to an exemplary aspect of the present invention includes forming a semiconductor device on the process object using the resist pattern formed on the process object using the method as described above. Further, a method of forming a semiconductor device according to an exemplary aspect of the present invention includes providing a resist layer including resist material on a base member including a photothermal conversion material to convert light energy into thermal energy, facing the resist layer with an etching object layer of a process object, irradiating a predetermined part of the base member with a light beam to transfer the resist material corresponding to the predetermined part to the etching object layer, and etching the etching object layer to form a corresponding pattern thereon to the pattern of the resist layer. According to an exemplary aspect of the present invention, since a resist pattern can be formed on the process object without any development processes in related art methods, semiconductor device including semiconductor element can fabricate with enhanced productivity.

An electro-optic device according to an exemplary aspect of the present invention includes a wiring pattern formed by the wiring pattern forming method described above. Further, an electro-optic device according to an exemplary aspect of the present invention includes a semiconductor device fabricated by the fabrication method of the semiconductor device described above. Further, an electronic apparatus of an exemplary aspect of the present invention includes an electro-optic device described above. According to an exemplary aspect of the present invention, an electro-optic device and the electronic apparatus including the same, which can efficiently be fabricated and is capable of providing required performance, can be provided. Note that, as the electro-optic device, liquid crystal displays, organic EL (electroluminescence) displays, and plasma displays can be cited.

The droplet ejection method described above can be realized by a droplet ejection device equipped with an ejection head. The droplet ejection device includes ink-jet devices equipped with an inkjet head. Inkjet heads of inkjet device can eject a constant amount of droplet of fluid materials including the functional fluid using the inkjet method, and for example, 1 through 300 nanograms of droplet of fluid materials can be ejected intermittently in a constant amount. Note that the droplet ejection device can be a dispenser device.

The fluid material denotes a media having viscosity enough to be ejected (dropping) from an ejection nozzle of an ejection head of a droplet ejection device. It is no object whether the fluid is aqueous or oil-based. It is enough to have fluid nature (viscosity) with which it can be ejected from an ejection nozzle or the like. It does not matter if the fluid material includes solid substances as long as it remains fluid as a whole. Further, a material included in the fluid material can be dissolved by being heated to a temperature higher than its melting point in a solvent, or dispersed as fine particles in a disperse medium, or added with other functional materials than the solvent, such as a dye or a pigment.

Further, the functional fluid described above denotes a fluid material containing a functional material, and brings out a required function when it is disposed on a substrate. As such a functional material, a liquid crystal display forming material to form a liquid crystal display including a color filter, an organic EL (electroluminescence) display forming material to form an organic EL display, a plasma display forming material to form a plasma display, and a wiring pattern forming material including metal to form a wiring pattern to circulate electric power, and so on can be cited.

### BRIEF DESCRIPTION OF THE DRAWINGS

FIG. 1 is a schematic showing an exemplary embodiment of a resist pattern forming system used for the resist pattern forming method according to the present invention;

FIGS. 2(a)-2(d) are schematics showing an exemplary embodiment of a resist pattern forming method according to the present invention;

FIG. 3 is a schematic showing another exemplary embodiment of a resist pattern forming system used for the resist pattern forming method according to the present invention;

FIG. 4 is a schematic showing another exemplary embodiment of a resist pattern forming method according to the present invention;

FIG. 5 is a schematic showing another exemplary embodiment of a resist pattern forming method according to the present invention;

FIG. 6 is a schematic showing another exemplary embodiment of a resist pattern forming method according to the present invention;

FIG. 7 is a schematic showing an exemplary embodiment of a wiring pattern forming method according to the present invention;

FIG. 8 is a schematic showing an ejection head used for a wiring pattern forming method according to an exemplary embodiment of the present invention;

FIG. 9 is a schematic showing a plasma display showing one example of an electro-optic device having a wiring pattern formed by a wiring pattern forming method according to an exemplary aspect of the present invention;

FIGS. 10(a)-10(f) are schematics showing one exemplary embodiment of a semiconductor device fabrication method according to the present invention, and showing one example of a thin film transistor fabrication process;

FIG. 11 is a schematic of an organic EL display showing one example of a electro-optic device having a semiconductor device fabricated by semiconductor device fabrication method according to an exemplary embodiment of the present invention; and

FIGS. 12(a)-12(c) are schematics showing examples of an electronic apparatus having an electro-optic device according to an exemplary embodiment the present invention.

### DETAILED DESCRIPTION OF EXEMPLARY EMBODIMENTS

Method of Forming a Resist Pattern

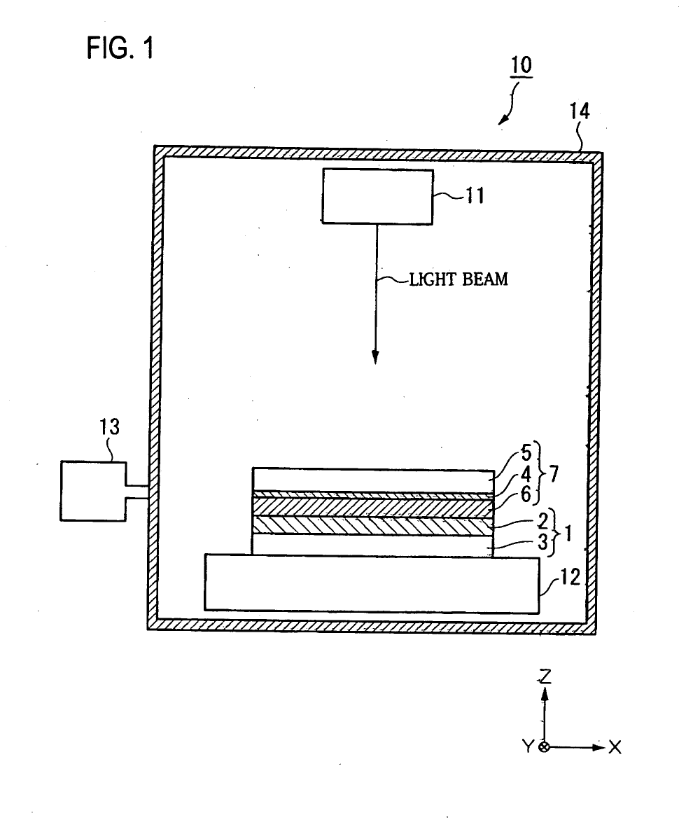

Hereinafter, a resist pattern forming method according to an exemplary aspect of the present invention is described with reference to the accompanying drawings. FIG. 1 is a schematic showing an exemplary embodiment of a resist pattern forming system used for the resist pattern forming method according to the present invention. In FIG. 1, the resist pattern forming system 10 is equipped with a laser beam source 11 to emit a laser beam having a predetermined wavelength and a stage 12 to support a process object 1. The process object 1 includes a substrate 3 and an etching object layer 2 provided on the upper surface of the substrate 3. The stage 12 to support the laser beam source 11 and the process object 1 is disposed in a chamber 14. An aspirator 13 capable of suctioning gas in the chamber 14 is connected to the chamber 14. In the present exemplary embodiment, a near-infrared semiconductor laser (the wavelength of 830 nm) is used as the laser beam source.

Here, it is assumed in the following description that an X-axis direction denotes a predetermined direction in a horizontal plane, a Y-axis direction denotes a direction perpendicular to the X-axis direction in the horizontal plane, and a Z-axis direction is a direction (the vertical direction) perpendicular to both the X-axis and the Y-axis.

A donor sheet 7 is adhered to the process object 1. The donor sheet 7 is composed of a base member 5 and a photothermal conversion layer 4 and resist layer 6 both formed on the base member 5. Each of the base member 5, the resist layer 6, and photothermal conversion layer 4 is provided as an independent layer from each other. The resist layer 6 is provided on a lower surface side of the base member 5, and the photothermal conversion layer 4 is also provided on the lower surface side of the base member 5, where the resist layer 6 is provided. The photothermal conversion layer 4 is provided between the base member 5 and the resist layer 6 so that the photothermal conversion layer 4 and the resist layer 6 are adjacent to each other. The resist layer 6 of the donor sheet 7 and the etching object layer 2 face each other. Further, the resist layer 6 and the etching object layer 2 are adhered to each other.

The stage 12 is provided so as to be movable in both the X-axis direction and the Y-axis direction while supporting the process object 1 and the donor sheet 7 adhered to the process object 1. By movement of the stage 12, the process object 1 and the donor sheet 7 can move with respect to the beam emitted from the beam source 11. Further, the stage 12 can move in the Z-axis direction as well. Note that, between the beam source 11 and the donor sheet 7 supported by the stage 12, there is disposed an optical system not shown in the drawings. The position of the donor sheet 7 (the process object 1) with respect to the focus of the optical system can be adjusted by moving the stage supporting the process object 1 and the donor sheet 7 in the Z-axis direction. Thus, the beam emitted from the beam source 11 irradiates the donor sheet 7 (the base member 5) supported by the stage 12.

As the base member 5, materials capable of transmitting the laser beam, such as a grass substrate or a transparent polymer can be used. As the transparent polymer, polyester, such as polyethylene terephthalate, polyacrylic resin, poly epoxy resin, polyethylene resin, polystyrene resin, polycarbonate, polysulfone, and so on can be cited. In case the base member 5 is made of transparent polymer, the thickness thereof may be between 10 and 500 μm. Being thus structured, for example, the base member can be formed like a strip to be wound as a roll, which can be transferred (moved) while supported by a rotating drum or the like.

Note that although the base member 5 is supported here by the stage 12, which is translated in both X and Y directions, if the base member 5 is supported by the rotating drum, the rotating drum can move in a horizontal translational direction (a scanning direction, the X direction), a rotational direction (the Y direction), and the vertical direction (the Z direction).

The photothermal conversion layer 4 is configured to include a photothermal conversion material to convert light energy into thermal energy. As the photothermal conversion material forming the photothermal conversion layer 4, any suitable material may be used, as long as the material can efficiently convert the laser beam into heat. A metal layer made of, for example, aluminum, other oxides and/or sulfides, or an organic layer made of polymer added with carbon black, graphite, or an infrared ray absorbing pigment or the like can be cited. As a infrared ray absorbing pigment, an anthraquinone pigment, a dithiol-nickel complex pigment, a cyanine pigment, azo cobalt complex pigment, a diimmonium pigment, a squalelium pigment, a phthalocyanine pigment, a naphthalocyanine pigment and so on can be cited. Further, using synthetic resin, such as epoxy resin as a binder, the binder resin including the photothermal conversion material dissolved or dispersed thereto can alternatively be provided on the base member 5. In this case, the epoxy resin functions as a curing agent which can cure the photothermal conversion layer 4 to be fixed on the base member 5. Further, the photothermal conversion material 4 can certainly be provided on the base member 5 without being dissolved or dispersed by the binder.

In case the metal layer is used as the photothermal conversion layer 4, it can be formed on the base member 5 utilizing the vacuum deposition method, the electron beam evaporation method, or the sputtering method. If the organic layer is used as the photothermal conversion layer 4, it can be formed on the base member 5 by a typical film coating method such as, for example, the extrusion coating method, the spin-coating method, the gravure coating method, the reverse roll coating method, the rod coating method, the micro gravure coating method, the knife coating method, or the like. In the coating process of the photothermal conversion layer 4, the static electricity charged on the surface of the base member 5 may be removed to uniformly form the functional fluid of the photothermal conversion layer on the base member 5. Therefore, static eliminating equipment may be installed in equipments used for the above methods.

The resist layer 6 is composed of a resist material. The resist material is composed of a material which presents etching resistance in an etching process described below. Any suitable material, such as, for example, novolak resin or phenol resin can be used for this purpose. Further, the resist layer 6 is composed of a material having transferability to (adhesiveness with) the etching object layer 2. The resist layer 6 can be formed on the photothermal conversion layer 4 (the base member 5) by a typical film coating method, such as, for example, the extrusion coating method, the spin-coating method, the gravure coating method, the reverse roll coating method, the rod coating method, the micro gravure coating method, or the like. In the coating process of the resist layer 6, the static electricity charged on the surface of the photothermal conversion layer 4 (the base member 5) may be removed to uniformly form the functional fluid of the resist layer on the photothermal conversion layer 4 (the base member 5), and therefore, static eliminating equipments are may be installed in equipments used for the above methods.

The substrate 3 of the process object 1 is composed of, for example, a glass plate, a synthetic resin film, or a semiconductor wafer. The etching object layer 2 is a layer to be etched in an etching process described below, and is composed of a film made of semiconductor, insulator, or electric conductor.

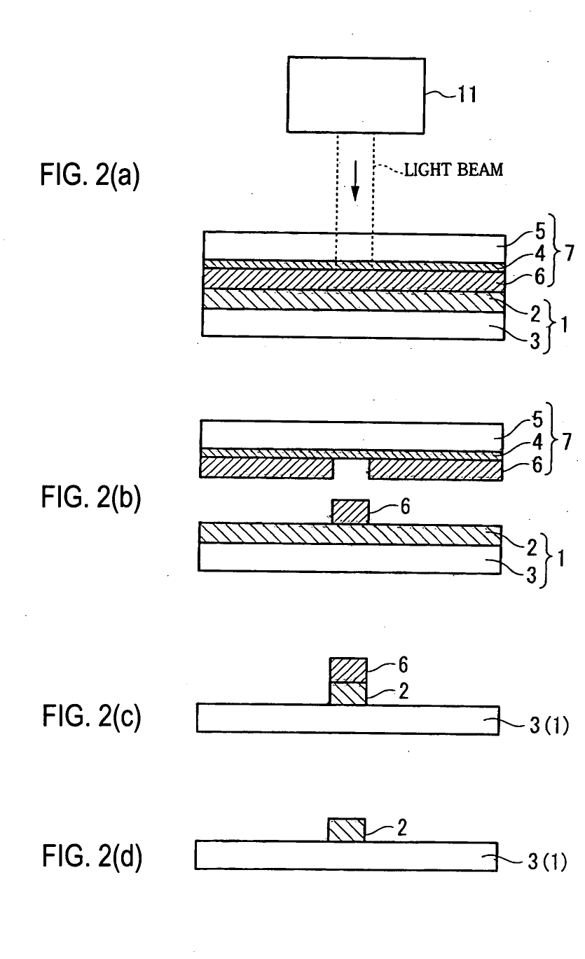

Hereinafter, a procedure of forming the resist pattern is described with reference to FIGS. 2(a)-2(d). As shown in FIG. 2(a), the resist layer 6 of the donor sheet 7 and the etching object layer 2 of the process object 1 are faced and then adhered to each other. In order to adhere the resist layer 6 to the etching object layer 2, while the resist layer 6 and the etching object layer 2 are facing each other, an aspirator 13 (See FIG. 1.) is driven to suck gas contained in a chamber 14 to reduce the pressure. Thus, a space between the resist layer 6 and the etching object layer 2 is also depressurized to be of negative pressure, thereby adhering the resist layer 6 with the etching object layer 2. Then, a laser beam having a predetermined beam diameter is irradiated from the upper surface side of the donor sheet 7 (the base member 5). By irradiation of the laser beam, corresponding parts of the base member 5 and the photothermal conversion layer 4 to the irradiated areas are heated. The photothermal conversion layer 4 converts light energy of the laser beam into thermal energy, and the thermal energy is provided to the resist layer 6 adjacent thereto. The part (a part adjacent to the interfacial surface with the photothermal conversion layer 4) of the resist layer 6, to which the thermal energy is provided, is heated to be, for example, in the molten state with a temperature higher than the glass transition temperature, and is transferred to the etching object layer 2 of the process object 1. In this case, only the corresponding regions of the resist layer 6 to the regions irradiated with the laser beam can be transferred. Therefore, the corresponding part of the resist layer 6 to the region irradiated with the laser beam is transferred to the etching object layer 2 of the process object 1.

The stage 12 is moved along the X-Y plane with respect to the laser beam irradiated thereto. Thereby the corresponding part of the resist layer 6 to the locus of movement of the stage 12 is transferred to the process object 1. Thus, the resist pattern is formed on the etching object layer 2 of the process object 1.

After the resist layer 6 is transferred to the etching object layer 6, driving of the aspirator 13 is stopped to release the reduced pressure condition (the negative pressure condition). Thereby, as shown in FIG. 2(b), the donor sheet 7 and the process object 1 are placed in a separable condition.

After transferring the resist layer 6 to the etching object layer 2, as shown in FIG. 2(c), the etching process is executed. The resist material forming the resist layer 6 has etching resistance. Accordingly, the resist layer 6 transferred on the etching object layer 2 functions as an etching mask. As the etching process, any switching etching processes, such as a dry etching process or a wet etching process can be adopted.

And, as shown in FIG. 2(d), the resist layer 6 on the process object 1 is removed (by ashing). Thereby the etching object layer 2 is formed as a pattern corresponding to the resist pattern.

As described above, by providing the photothermal conversion layer 4 on the base member 5 the light energy of the irradiated light can be efficiently converted into thermal energy. By providing the thermal energy to the resist layer 6, the corresponding portion of the resist layer 6 to the light irradiated region can be transferred to the process object 1 (the etching object layer 2). Therefore, by irradiating a predetermined region on the base member 5 corresponding to the resist pattern to be formed, the resist material of the resist layer 6 corresponding to the predetermined region can be transferred to the process object 1, thus forming a desired resist pattern on the process object 1. Further, since the photothermal conversion layer 4 is provided, the near-infrared laser beam or the like, instead of electron beams or ultraviolet rays, can be used to provide sufficient thermal energy to the resist layer 6 to transfer the resist layer 6. Therefore, the range of options for the light emission device to be used can be broadened and without using any expensive and large-scale light emission devices, the resist layer 6 can be transferred in good condition from the donor sheet with sufficient thermal energy.

Since in exemplary aspects of the present invention a desired resist pattern can be formed on the process object 1 only by irradiating with light and any development processes in related art methods are not required, productivity can be enhanced. Further, unlike with related art resist materials, it is not necessary to disperse photoacid generators or photobase generators to the resist layer, nor to install a photosensitive group to the principal chain structure of the resist material. Specifically, according to an exemplary aspect of the present invention, the resist material may only include a functional group having adhesiveness with the process object 1 and a functional group having the etching resistance, thus making the materials design easier.

Note that, although in the present exemplary embodiment a predetermined resist pattern is formed on the process object 1 (the etching object layer 2) by moving the stage supporting the process object 1 and the donor sheet 7, the light beam to be irradiated can certainly be moved while the process object 1 and the donor sheet 7 are stopped, or both of the process object 1, the donor sheet 7 and the light beam can certainly be moved. Still further, in case of moving both of the process object 1 and the donor sheet 7, the configuration in which they are moved while being supported by the rotating drum can be adopted instead of the configuration in which they are moved in the X-Y plane with the stage 12.

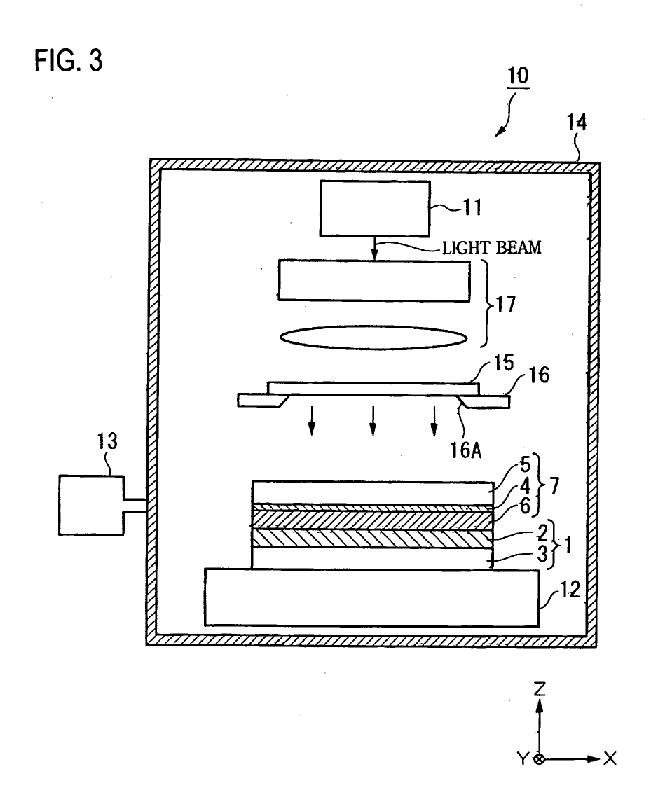

In forming the resist pattern, as shown in FIG. 3, a mask 15 having a pattern corresponding to the resist pattern to be formed can be irradiated with light to irradiate the donor sheet 7 with the light passing through the mask 15. In the example shown in FIG. 3, the mask 15 is supported by a mask support section 16 having an opening 16A to transfer the light passing through the mask 15. The light beam emitted from the light beam source 11 is converted, by an optical system 17, into illumination light having homogeneous illuminance distribution to illuminate the mask 15. The donor sheet 7 supported by the stage 12 is irradiated with the light passing through the mask 15. The heat generated in accordance with the irradiated light causes a part of the resist layer 6 to be transferred to the process object 1 to form the resist pattern. By using the mask 15, a resist pattern finer than the diameter of the beam emitted from the laser beam source 11 can be formed. In contrast, as described with reference to FIG. 1, by irradiating with light while relatively moving the light beam and the donor sheet 7 (the process object 1), problems associated with manufacturing the mask 15 can be reduced.

Note that, although in the example shown in FIG. 3, the donor sheet is irradiated with light while the mask 15 and the donor sheet 7 are separated from each other, the donor sheet can be irradiated with the light passing through the mask 15 while the mask 15 is irradiated with the mask 15 and the donor sheet 7 are adhered with each other.

Note that as the light beam source 11, a mercury lamp, a halogen lamp, a xenon lamp, or a flash lamp, for example, can be used other than the near-infrared semiconductor laser. Further, all of general purpose laser devices other then the near-infrared laser, such as a ultraviolet laser, can also be used.

Note that, although in the above exemplary embodiment, it is described that the process object 1 includes the substrate 3 and the etching object layer 2 provided on the substrate 3 and the etching object layer 2 is etched after the resist layer 6 is transferred on the etching object layer 2, the resist layer 6 is directly transferred on the substrate without providing the etching object layer 2.

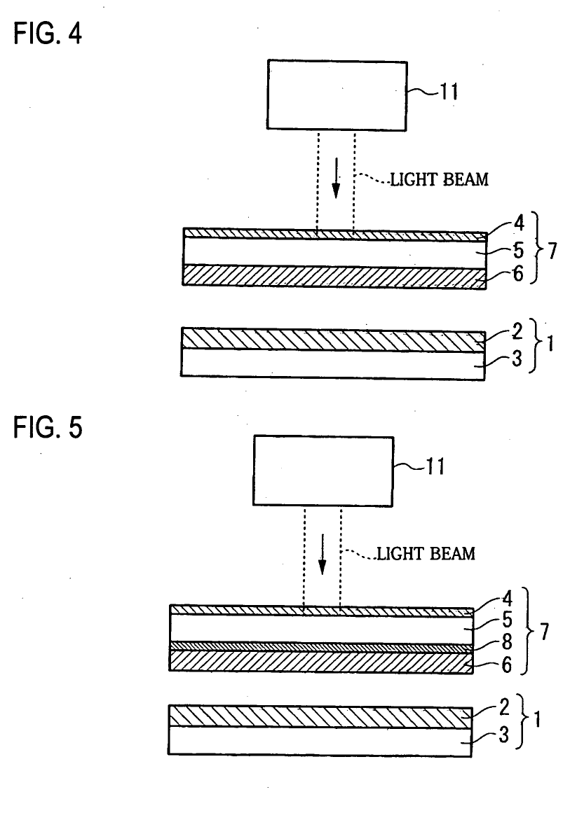

As shown in FIG. 4, an alternative configuration can be adopted, in which the photothermal conversion layer 4 is provided on the upper surface side of the base member 5 where the resist layer 6 is not provided. In this case, the thickness of and the materials for the base member 5 should be selected to be the most suitable in order to efficiently transfer the thermal energy generated from the photothermal conversion layer 4 to the resist layer 6 disposed on the lower surface side thereof. Note that the photothermal conversion layers 4 can be provided on both the upper and the lower surfaces of the base member 5.

In case the photothermal conversion layer 4 is provided, the light having a wavelength suitable for the photothermal conversion material may be irradiated. That is, since the wavelength band of light effectively absorbed by a photothermal conversion material differs by photothermal conversion materials, by irradiating a photothermal conversion material with the light having a wavelength suitable for the photothermal conversion material, the light energy can efficiently be converted into the thermal energy. Specifically, the photothermal conversion material to be used is selected in accordance with the light to be irradiated. In the present exemplary embodiment, since the near-infrared semiconductor laser (the wavelength of 830 nm) is used as the laser beam source, the materials having properties of absorbing light in a range of infrared light through visible light may be used as the photothermal conversion material.

Note that, although in the above exemplary embodiments, the photothermal conversion material is formed as a layer (the photothermal conversion layer) independent from the base member 5 or the resist layer 6, an alternative configuration in which the photothermal conversion material is dispersed to the base member 5 or an alternative configuration in which the photothermal conversion material is dispersed to the resist layer 6 can also be adopted. Even by the above configurations, the light energy of the irradiated laser beam can be converted into thermal energy which is in turn provided to the resist layer 6. Note that, on the base member 5 to which the photothermal conversion material is dispersed, the photothermal conversion layer 4 can additionally be provided.

As shown in FIG. 5, a gas generation layer 8 including a gas generation material, which generates gas in response to light irradiation or application of heat, can be provided between the base member 5 and resist layer 6. The gas generation material causes decomposition reaction to discharge nitrogen gas or hydrogen gas when it absorbs light or thermal energy converted from light energy, and functions to provide energy to separate the resist layer 6 from the base member 5 by the generated gas. As such a gas generation material, at least one material selected from a group including pentaerythoritol tetranitrate (PETN) and trinitrotoluene (TNT) can be cited.

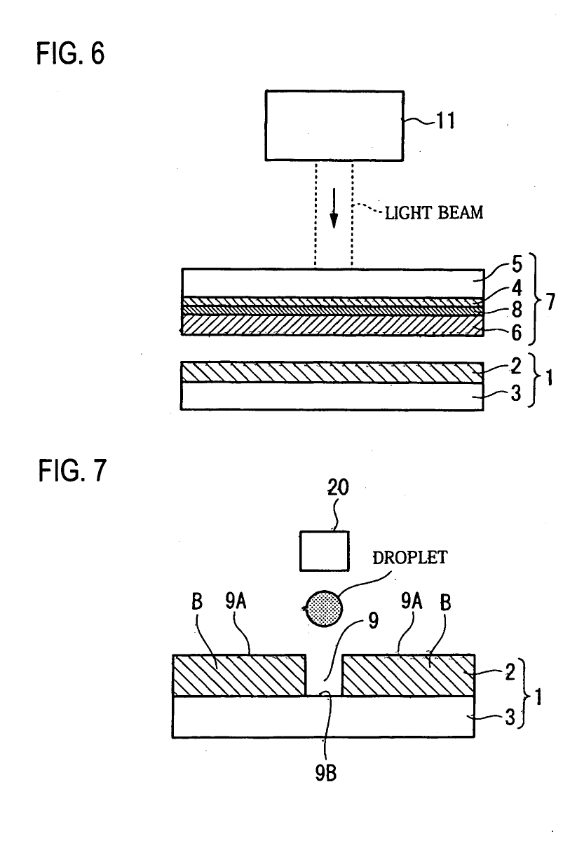

Further, as shown in FIG. 6, in the case of the configuration providing the photothermal conversion layer 4 on the lower surface side of the base member 5, the gas generation layer 8 can be provided between the photothermal conversion layer 4 and the resist layer 6. Alternatively, the gas generation layer 8 can be provided between the base member 5 and the photothermal conversion layer 4. Further, the gas generation material can be dispersed in the photothermal conversion layer 4. Further, the gas generation material can be dispersed in the base member 5.

Further, in the exemplary embodiments shown in FIG. 2 or other drawings, an interlayer to homogenize the photothermal conversion behavior of the photothermal conversion layer 4 can be provided between the photothermal conversion layer 4 and the resist layer 6. As a material to form such an interlayer, a resin material which fulfills the requirements described above can be cited. Such an interlayer can be formed by depositing and then drying a resin compound having a predetermined composition on the surface of the photothermal conversion layer 4 using suitable coating method, such as, for example, a spin coating method, a gravure coating method, or a dye coating method. When a laser beam is irradiated, the light energy thereof is converted into thermal energy by the behavior of the photothermal conversion layer 4. Then the thermal energy is homogenized by the behavior of the interlayer. Therefore, the corresponding portion of the resist layer 6 to the irradiated region is equally provided with the thermal energy.

Further, in the exemplary embodiments shown in FIG. 2 or other drawings, a heat transfer layer or an exfoliation layer can be provided between the photothermal conversion layer 4 and the resist layer 6. As materials to compose the heat transfer layer or the exfoliation layer, for example, poly(alpha-methylstyrene) acid can be cited. Further, the thicknesses of the heat transfer layer and the exfoliation layer are not limited, but may preferably be about 1 μm respectively.

Still further, in order to enhance the mold releasing property of the photothermal conversion layer 4 and the resist layer 6, mold lubricant can be included in the photothermal conversion layer 4. As the mold lubricant, any suitable mold lubricants including, for example, solid or wax type materials, such as polyethylene wax, amide wax, fine powder of silicone resin, or fine powder of fluorinated resin; fluorinated detergents or phosphoric ester detergents; a type of oil such as paraffinic oil, silicone oil, or fluorinated oil can be applied. In particular, silicone oil is preferable. As the silicone oil, other than non-denatured one, various denatured silicone oil, such as carboxy denatured silicone oil, amino denatured silicone oil, epoxy denatured silicone oil, polyether denatured silicone oil, or alkyl denatured silicone oil can be used independently or in combination of two or more thereof.

Method of Forming a Wiring Pattern

Hereinafter, a method of forming a wiring pattern on the substrate 3 of the process object 1 is described. FIG. 7 shows a view in which a bank B is formed by patterning the etching object layer 2 having a groove section 9 on the substrate 3 by executing an etching process and an ashing process after transferring the resist layer 6 on the etching object layer 2 by the resist pattern forming method according to an exemplary aspect of the present invention. In the present exemplary embodiment, a droplet ejection method (the inkjet method), in which droplets of functional fluid including a material to form the wiring pattern are ejected, is used to deposit the wiring pattern forming material on the substrate 3. The bank B is provided so as to partition wiring pattern forming regions previously defined on the substrate 3. In the droplet ejection method, while an ejection head 20 and the substrate 3 face each other, the droplets of the functional fluid including the wiring pattern forming material are ejected from the ejection head 20 toward the groove 9 between the banks B, B.

Note that, as an ejection technology used for the droplet ejection method, the charge control method, the pressure vibration method, electrothermal conversion method, electrostatic absorption method, electromechanical conversion method and so on can be cited. In the charge control method, the material is charged by a charge electrode and ejected from an ejection nozzle while its flight orientation is controlled by a deflection electrode. Further, in the pressure vibration method, the material is ejected from the tip of the nozzle by being applied with very high pressure of about 30 kg/cm², and when no control voltage is applied, the material is forwarded straight to be ejected from the ejection nozzle, and when the control voltage is applied, an electrostatic repelling force is generated in the material to cause the material to fly in various directions and not to be ejected from the ejection nozzle. Further, in the electrothermal conversion method, the material is rapidly vaporized to generate a bubble by a heater provided in a chamber containing the material, and the material in the chamber is ejected by a pressure caused by the bubble. In the electrostatic absorption method, minute pressure is applied to a chamber containing the material to form a meniscus at the ejection nozzle. Then an electrostatic absorption force is applied in this condition to take the material out of the nozzle. In the electromechanical conversion method, the characteristics of the piezoelectric element that becomes distorted in response to a pulsed electric signal are utilized, and when the piezoelectric element distorts, pressure is applied to a chamber containing the material via an elastic member to push the material out of the chamber to eject it from the ejection nozzle. Other than the above methods, a method utilizing viscosity alteration of fluid by electric field or a method for flying the material by discharge sparks can also be adopted. The droplet ejection method has advantages that there is little waste in using the material and that a desired amount of material can precisely be disposed on a desired position. Note that the weight of one droplet of the material ejected by the droplet ejection method is, for example, 1 through 300 nanograms. In the present exemplary embodiment, the electromechanical conversion method (the piezoelectric method) is used.

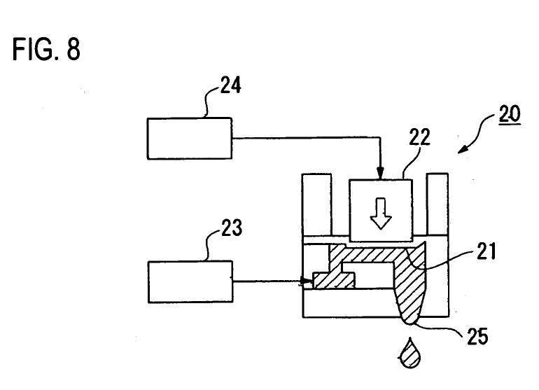

FIG. 8 is a view for explaining the principle of ejecting the functional fluid (liquid material) according to the piezoelectric method. In FIG. 8, the ejection head 20 is equipped with a fluid chamber 21 to contain the functional fluid (the liquid material including the wiring pattern forming material) and a piezoelectric element 22 disposed adjacent to the fluid chamber 21. The functional fluid is supplied to the fluid chamber 21 via a supply system 23 including a material tank to contain the functional fluid. The piezoelectric element 22 is connected to a drive circuit 24, and by applying voltage to the piezoelectric element 22 via the drive circuit 24 to distort the piezoelectric element 22, the fluid chamber is also distorted to eject the functional fluid from the ejection nozzle 25. In this case, an amount of distortion of the piezoelectric element 22 can be controlled by altering the value of the applied voltage. Further, a speed of distortion of the piezoelectric element 22 can be controlled by altering the frequency of the applied voltage. Since no substantial heat is applied to the material in ejecting droplet using the piezoelectric method, it has an advantage that the composition of the material is hardly affected.

A procedure of forming the wiring pattern is hereinafter described. After forming the banks B, B by the method described above, first, a residual disposition process for disposing the residual dross in the bottom portion 9B of the groove 9 between the banks B, B may be executed. By irradiating the bottom portion 9B of the groove 9 with light such as, for example, an ultraviolet ray (UV) as the residual disposition process, the residual dross, particularly the organic residual dross remaining in the bottom portion 9B can effectively be removed by photoexcitation. Note that the residual dross can also be removed by the O₂ plasma process as the residual disposition process using process gas including, for example, oxygen (O₂) as predetermined process gas. Further, the ultraviolet ray irradiation process or the O₂ plasma process also functions as a lyophilicity providing process for providing lyophilicity to the bottom portion 9B (the exposed portion of the substrate 3), and by providing lyophilicity to the bottom portion 9B (the exposed portion of the substrate 3), as described below, the bottom portion 9B can be wetted with the droplet of the functional fluid disposed on the groove 9 to allow the functional fluid to be spread over the bottom portion 9B.

Subsequently, a lyophobicity providing process is executed to the banks B to provide lyophobicity to the surface thereof. As the lyophobicity providing process, for example, the plasma process method (the CF₄ plasma process method) using tetrafluoromethane as the process gas in the atmosphere can be adopted. Note that the process gas is not limited to tetrafluoromethane (tetrafluorocarbon), but other fluorocarbon gases can also be used. Furthermore, process gases other than fluorinated gases can be used providing they can provide lyophilicity with the functional fluid. Further, as the lyophobicity providing process, any suitable method, such as a method (a self assembly layer method, a chemical vapor phase evaporation method) of processing with FAS (fluoroalkylsilane), a conjugated coating method, or a method of providing lyophobicity with gold-thiol can be adopted. Since the bank B is provided with lyophobicity, when a part of the droplet ejected from the ejection head 20 lands on the upper surface 9A of the bank B, the part of the droplet is repelled by the bank B, whose surface is provided with lyophobicity, to flow down to the groove 9 defined between the banks B, B. Accordingly, the ejected functional fluid is precisely positioned between the banks B, B on the substrate 3.

Note that although the lyophobicity providing process for the banks B, B slightly affects the lyophilicity of the bottom portion 9B (the exposed portion of the substrate 3) between the banks, which has previously been treated to have lyophilicity, particularly in case the substrate 3 is made of glass or the like, the lyophilicity of the substrate 3 is practically maintained because no adoption of a fluoric group occurs during the lyophobicity providing process. Further, this lyophobicity providing process can be omitted by previously dispersing an adjusting material having lyophobicity in the bank B (the etching object layer 2).

Subsequently, a material disposition process to dispose droplets of functional fluid including the wiring pattern forming material, between the banks B, B on the substrate 3 using the ejection head 20 is executed. In this process, an organo-silver compound is used as a conductive material composing the wiring pattern forming material, and diethylene glycol diethyl ether is used as a solvent (dispersionmedium). The functional fluid including the organo-silver compound is ejected. In the material disposition process, as shown in FIG. 7, the functional fluid including the wiring pattern forming material, is ejected from the ejection head 20 as a droplet. The ejected droplet is disposed on the groove 9 between the banks B, B in the substrate 3. In this step, since the wiring pattern forming region, to which the droplet is ejected, is partitioned by the bank B, the droplet is prevented from expanding beyond a predetermined region. Furthermore, since the banks B, B are provided with lyophobicity, even if a part of the ejected droplet lands on the bank B, it flows down to the groove 9 between the banks. Still further, since the bottom portion 9B of the groove 9, where the substrate is exposed, is provided with lyophilicity, the ejected droplet becomes easier to spread over the bottom portion 9B. Thus the functional fluid is evenly disposed within a predetermined region.

Note that dispersion liquid composed of electrically conductive fine particles dispersed in dispersion medium can also be used as the functional fluid. Metal fine particles including at least one of, for example, gold, silver, copper, aluminum, palladium, and nickel, or oxides thereof, fine particles of electrically conductive polymers or superconductive materials can be used as the electrically conductive fine particles. The dispersion medium is not limited providing it can disperse the electrically conductive fine particles described above and does not cause any agglutination. For example, other than water, alcohol, such as methanol, ethanol, propanol, or butanol, carbon hydride compounds, such as n-heptane, n-octane, decane, dodecane, tetradecane, toluene, xylene, cymene, durene, indene, dipentene, tetrahydronaphthalene, decahydronaphthalene, or cyclohexylbenzene, etherates, such as ethyleneglycoldimethylether, ethyleneglycoldiethylether, ethyleneglycolmethylethylether, diethyleneglycoldimethylether, diethyleneglycoldiethylether, diethyleneglycolmethylethylether, 1,2-dimethoxyethane, bis(2-methoxyethyl)ether, or p-dioxane, and further polar compounds, such as propylene carbonate, γ-butyrolactone, N-nethyl-2-pyrrolidone, dimethylformamide, dimethylsulfoxide, or cyclohexanone can be exemplified. In the above compounds, in view of dispersibility of the fine particles and stability of the dispersion liquid, further facility of applying to the droplet ejection method, water, alcohol, carbon hydride compounds, and etherates may be used and preferably, water and carbon hydride compounds can be cited.

After the material disposition process (the droplet ejection), a baking process is executed. By executing the baking process on the functional fluid including the electrically conducting material, the conductivity can be obtained. Particularly in case of the organo-silver compounds, the conductivity is expressed by removing the organic component by the baking process to make the silver particles remain. Therefore, at least one of a heat treatment and a light treatment is executed, as the baking process, on the substrate 3 after the material disposition process. The heat treatment and the light treatment are usually executed in the atmosphere, if necessary, they can also be executed in an environment of inactive gas, such as nitrogen, argon, or helium. The process temperature of the heat treatment and the light treatment is appropriately decided taking the boiling point (steam pressure) of the solvent, the nature or pressure of the environmental gas, dispersibility of the fine particles or organo-silver compounds, thermal behavior of oxidation, presence or absence or an amount of a coating material, a sustainable temperature of the base member, and so on into consideration. For example, the organo-silver compounds need to be baked at 200 degrees centigrade to remove the organic components. Further, in case of using a substrate made of for example plastic, it may be executed at a temperature higher than the room temperature and not higher than 100 degrees centigrade. The electrically conductive material (the organo-silver compound) after the ejection process is transferred to a wiring pattern having conductivity derived from the silver particles remaining through the above process.

Note that the wiring pattern forming material can be stacked as a plurality of layers by repeating the material disposition process and an intermediate drying process (or the baking process) by turns.

Note that, the banks B existing on the substrate 3 can be removed after the baking process. For example, the banks B can be removed from the substrate 3 by cleaning with predetermined solvent.

Plasma Display Device

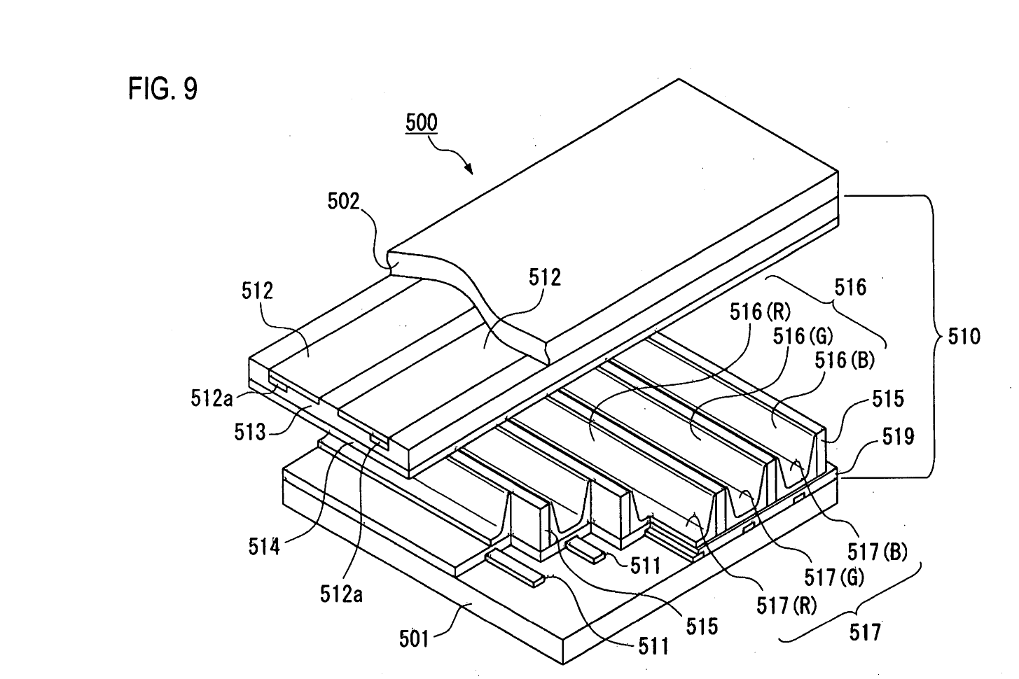

A plasma display (a plasma display device) is hereinafter described with reference to FIG. 9 as one example of an electro-optic device having a wiring pattern formed by the wiring pattern forming method according to an exemplary aspect of the present invention. FIG. 9 is a schematic showing a plasma display 500 having an address electrode 511 and a bus electrode 512a fabricated thereon. The plasma display 500 is mainly composed of a pair of glass substrates 501, 502 disposed so as to face to each other and discharge display section 510 formed between the substrates.

The discharge display section 510 composed of a plurality of discharge cells 516 integrated with each other is arranged so that three of the discharge cells, a red discharge cell 516(R), a green discharge cell 516(G), and a blue discharge cell 516(B) form one pixel. The address electrodes 511 are formed on the upper surface of the (glass) substrate 501 with a predetermined interval to form stripes. A dielectric layer 519 is formed to cover the address electrodes 511 and the upper surface of the substrate 501, and further, partitions 515 are formed on the dielectric layer 519 between the corresponding two of the address electrodes 511 and along the corresponding address electrode 511. Note that, the partitions 515 are divided (not shown in the drawings) at a predetermined position in the longitudinal direction at a predetermined interval in a direction perpendicular to the address electrodes 511, to form substantially rectangular regions defined by partitions adjacent to both the right and the left sides in the width direction of the address electrodes 511 and the partitions extended in a direction perpendicular to the address electrodes 511. The discharge cells 516 are formed corresponding to the rectangular regions, and one pixel is formed of three of these rectangular regions. Further, a fluorescent material 517 is disposed inside the rectangular region zoned by the partition 515. The fluorescent materials 517 emit fluorescence of one of red, green, and blue. The red fluorescent material 517(R) is disposed on the bottom of the red discharge cell 516(R), and the green fluorescent material 517(G) is disposed on the bottom of the green discharge cell 516(G), and the blue fluorescent material 517(B) is disposed on the bottom of the blue discharge cell 516(B).

Next, a plurality of transparent display electrodes 512 made of ITO is formed on the glass substrate 502 in a direction perpendicular to the address electrode 511 with a predetermined interval to form stripes. Further the bus electrode 512a made of metal is formed to complement ITO having substantial resistance. Further, a dielectric layer 513 is formed to cover the electrodes, a protective layer 514 made of MgO or the like is further formed. Then, the two substrates, substrate 501 and glass substrate 502 are adhered to each other so that the address electrodes 511 and the display electrodes 512 are faced perpendicular to each other. Then the space enclosed by the substrate 501, the partition 515, and the protective layer 514 formed on the side of the glass substrate 502 is evacuated and filled with rare gas to complete the discharge cell 516. Note that, a pair of the display electrodes 512 formed on the side of the glass substrate 502 is disposed for each discharge cell 516. The address electrode 511 and the display electrode 512 are connected to an alternate current power source not shown in the drawings, the fluorescent 517 is excited to emit light in a necessary position of the discharge display section 510 by applying electricity to the respective electrodes, thus presenting color display.

In the present exemplary embodiment, particularly the address electrodes 511 and bus electrode 512a are formed by the wiring pattern forming method according to an exemplary aspect of the present invention. Specifically, in view of advantages in patterning, the address electrode 511 and the bus electrode 512a are formed by ejecting and then drying or baking the functional fluid composed of a metal colloid material (e.g., gold-colloid or silver-colloid) or electrically conductive fine particles (e.g., a metal fine particles) dispersed therein. Further, the fluorescent 517 can also be formed by ejecting by the ejection head 20 and then drying or baking the functional fluid composed of the fluorescent material dissolved by the solvent or dispersed in the dispersion medium.

Thin Film Transistor

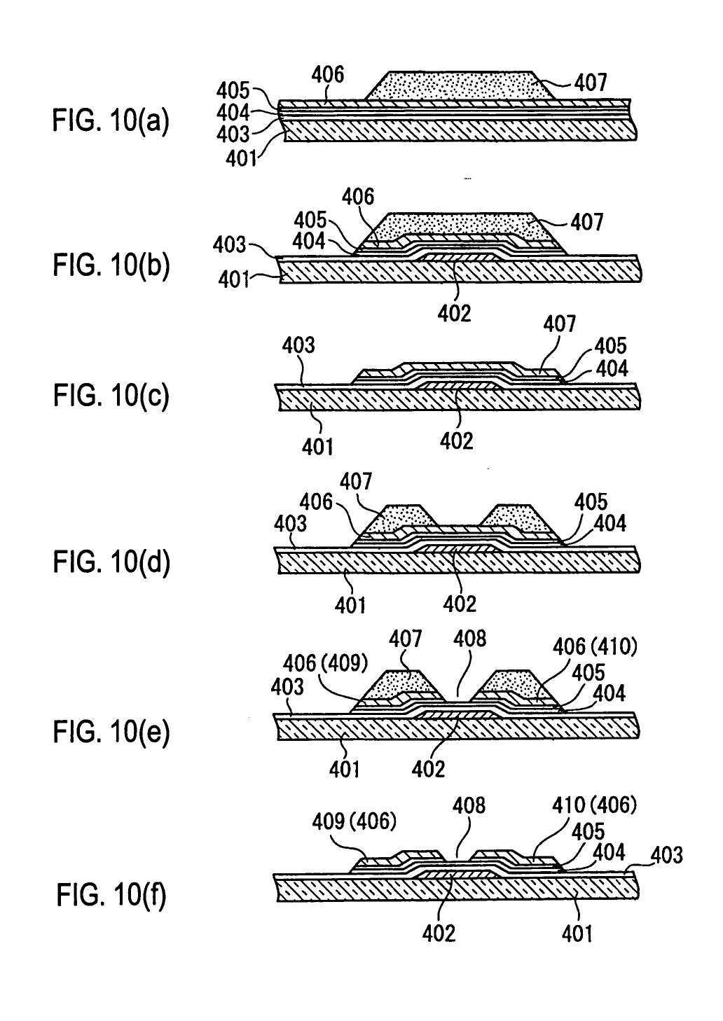

A procedure of forming a thin film transistor is hereinafter described as an example of forming a semiconductor device using the resist pattern according to an exemplary aspect of the present invention. As shown in FIG. 10(a), a gate insulation layer 403, an a-Si layer 404 which is an active semiconductor layer composed of non-doped amorphous silicon, N⁺a-Si layer 405 composed of silicon doped with phosphorous or the like with high concentration, and a metal layer 406 to form a source/drain electrode, are sequentially stacked on a substrate 401 on which a gate electrode is formed. Then a resist layer 407 is patterned on a part of the metal layer 406 to form a source/drain electrode using resist pattern forming method according to an exemplary aspect of the present invention. Then, as shown in FIG. 10(b), the a-Si layer 404, the N⁺a-Si layer 405, and a metal layer 406 to form a source/drain electrode is etched, and as shown in FIG. 10(c), the resist layer 407 is ashed. Then, as shown in FIG. 10(d), the resist layer 407 is again formed based on the resist pattern forming method according to an exemplary aspect of the present invention. And then, by etching, as shown in FIG. 10(e), a part of N⁺a-Si layer 405 corresponding to a channel section 408, and the metal layer 406 for forming a source/drain electrode, and then ashing the resist layer 407, as shown in FIG. 10(f), the cannel section 408, the source electrode 409, and the drain electrode 410 can be formed. The thin film transistor is completed by forming a pixel electrode, not shown in the drawings, to be connected to the drain electrode 410.

Organic EL Display

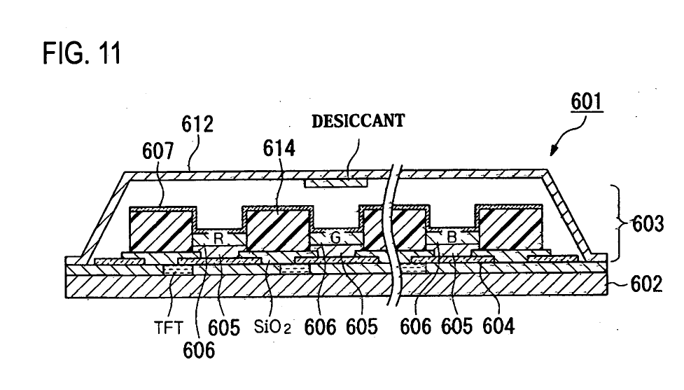

An organic EL (electroluminescence) display is hereinafter described as an example of the electro-optic device comprising the thin film transistor (semiconductor device) with reference to FIG. 11

In FIG. 11, an organic EL display 601 includes a light transmissive substrate (light transmissive layer) 602, an organic EL element (light emitting element) 603 provided on one surface side of the substrate 602 and composed of a hole injection/transfer layer 605 and a light emitting layer (EL layer) 606 having mainly an organic electroluminescence material sandwiched between a pair of electrode (an anode 604 and a cathode 607), a thin film transistor TFT provided on one surface side of the substrate 602 and connected to the anode (a pixel electrode) 604, and a seal substrate 612. The light emitting layer 606 is formed of three colored light emitting layer, a red (R) light emitting layer, a green (G) light emitting layer, and a blue (B) light emitting layer. Further, the seal substrate 612 and substrate 602 are adhered by an adhesive layer. The organic EL element 603 is sealed by the seal substrate 612 and the adhesive layer. Note that, the organic EL display 601 shown in FIG. 11 is a type (a bottom emission type or a substrate side emission type) in which the emitted light from the light emitting layer 606 is taken out from the substrate 602 side.

As a material to form the substrate 602, transparent or translucent materials capable of transmitting light, for example, transparent glass, quartz, sapphire, or transparent synthetic resin, such as polyester, polyacrylate, polycarbonate, or polyetherketone can be cited. In particular, inexpensive glass is may be used as the material to form the substrate 602.

As the seal substrate 612, for example, a glass substrate is used. But as long as it is transparent and has an excellent gas barrier property, other members than the grass substrate, such as a plastic substrate, a plastic laminate film, or a laminate mold substrate, or a glass laminate film can also be used. Further, a material capable of absorbing ultraviolet beam is may be used as the protective layer.

The anode (the pixel electrode) 604 is a transparent electrode composed of indium tin oxide (ITO) or the like, capable of transmitting light. As the material of the hole injection/transfer layer 605, for example, polymeric material, such as polythiophene, polystyrenesulfonate, polypyrrole, polyaniline, and their derivatives can be exemplified. As a material to form the light emitting layer 606, a polymeric luminescence or a small molecular organic luminescent dye, specifically, various light emitting materials, such as fluorescence materials or phosphorescence materials can be used. In the conjugated polymers having the light emitting property, those including arylenevinylene or polyfluorene structure are preferable. Note that, if necessary, an electron transfer layer or an electron injection layer can be provided between the cathode 607 and the light emitting layer 606.

The organic EL element 603 is disposed on an region defined by the bank 614, and the ejection head 20 is used for forming the organic EL element 603.

Although not shown in the drawings, the organic EL display of the present exemplary embodiment is an active matrix type. Accordingly, a plurality of data lines and a plurality of scanning lines are, in practice, disposed on the substrate 602 like a grid. And, in each pixel defined by the data lines and scanning lines and disposed in a matrix, the organic EL element 603 is connected via drive TFTs, such as switching transistors and driving transistors. Then, when a drive signal is applied via the data lines and scanning lines, electrical current flows between the electrodes to cause the light emitting layer 606 of the organic EL device 603 to emit light to outside of the substrate 602, thus putting on the pixel.

Note that although an example of applying the thin film transistors to the organic EL display is described here, the thin film transistors according to an exemplary embodiment of the present invention can certainly be applied to other displays having switching elements, such as a liquid crystal display.

Electronic Apparatus

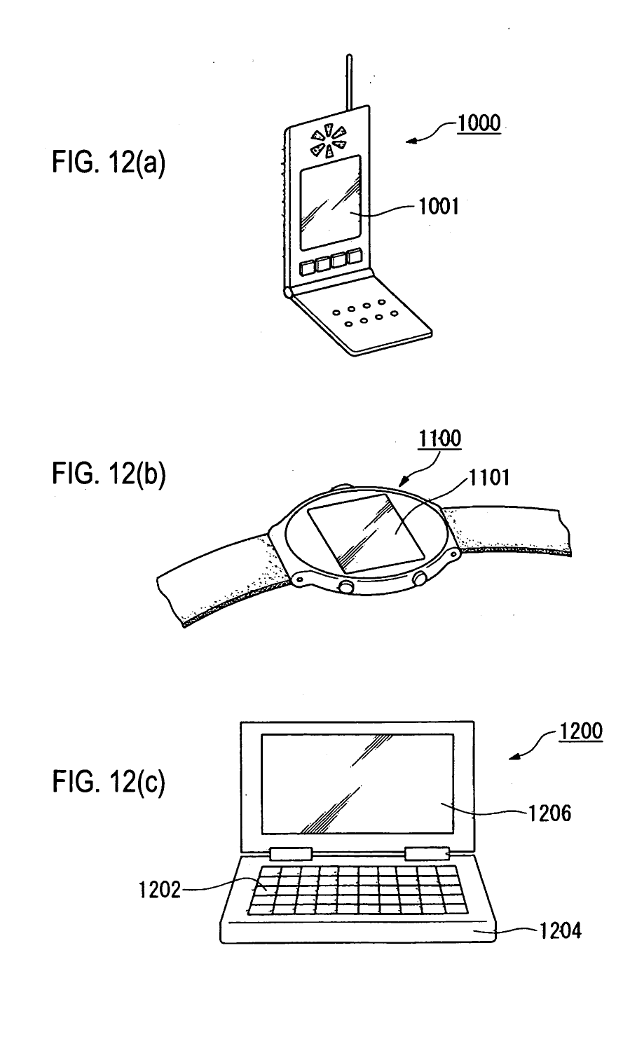

An application example of an electronic apparatus equipped with the electro-optic devices (the organic EL display, the plasma display, and the liquid crystal display) is hereinafter described. FIG. 12(a) is a schematic showing an example of a cellular phone. In FIG. 12(a), a reference numeral 1000 denotes a body of the cellular phone, and a reference numeral 1001 denotes the display section applying the electro-optic device described above. FIG. 12(b) is a schematic showing an example of a wristwatch type of electronic apparatus. In FIG. 12(b), a reference numeral 1100 denotes a body of the wristwatch, and a reference numeral 1101 denotes the display section applying the electro-optic device described above. FIG. 12(c) is a schematic showing an example of a portable data processing device, such as a word processor or a personal computer. In FIG. 12(c), a reference numeral 1200 denotes a data processing device, a reference numeral 1202 denotes an input section, such as a keyboard, a reference numeral 1204 denotes a body of the data processing device, and a reference numeral 1206 denotes a display section applying the above electro-optic device. Since the electronic apparatus shown in FIGS. 12(a) through 12(c) are equipped with the electro-optic device according to any of the present exemplary embodiments, the electronic apparatus equipped with display sections capable of providing excellent display quality and blight screens can be realized.

Note that, in addition to the examples described above, liquid crystal televisions, video cassette recorders of viewfinder types or direct monitor types, car navigation devices, pagers, personal digital assistants, electric calculators, word processors, work stations, picture phones, POS terminals, electronic papers, apparatus equipped with a touch panel and so forth, can be cited as further examples thereof. The electro-optic device of an exemplary embodiment of the present invention can also be applied to the display section of the electronic apparatus described above.

1. A method of forming a resist pattern, comprising:
providing a resist layer including a resist material on a base member including a photothermal conversion material to convert light energy into thermal energy;
facing the resist layer with a process object; and
irradiating a predetermined part of the base member with a light beam so as to transfer the resist material corresponding to the predetermined part to the process object, thereby patterning the resist material on the process object.

2. The method of forming a resist pattern according to claim 1, further including providing the base member, the resist layer, and the photothermal conversion layer independently from each other.

3. The method of forming a resist pattern according to claim 2, further including providing the photothermal conversion layer between the base member and the resist layer.

4. The method of forming a resist pattern according to claim 2, further including providing the resist layer on one surface of the base member, and providing the photothermal conversion layer on another surface of the base member.

5. The method of forming a resist pattern according to claim 1, further including dispersing t h e photothermal conversion material in the base member.

6. The method of forming a resist pattern according to claim 1, further including dispersing the photothermal conversion material in the resist layer.

7. The method of forming a resist pattern according to claim 1, further comprising:
providing a gas generation layer between the base member and the resist layer, the gas generation layer including a gas generation material that generates gas in response to one of irradiation of a light beam and heat.

8. The method of forming a resist pattern according to claim 1, further including dispersing the gas generation material in the base member.

9. The method of forming a resist pattern according to claim 1, further including irradiating the base member with the light beam passing through a mask having a predetermined pattern.

10. The method of forming a resist pattern according to claim 1, further including irradiating the base member with the light beam while the base member and the process object move relative to the light beam.

11. The method of forming a resist pattern according to claim 1, further including irradiating the base member with the light beam while the resist layer and the process object are adhered to each other.

12. The method of forming a resist pattern according to claim 11, the irradiating further comprising:
depressurizing a space between the resist layer and the process object after the facing to make the resist layer and the process object be adhered to each other.

13. The method of forming a resist pattern according to claim 12, further comprising:
releasing the depressurized condition after the irradiation to allow the resist layer and the process object be separated from each other.

14. The method of forming a resist pattern according to claim 1, further comprising:
providing the process object with an etching object layer; and
etching the etching object layer after the irradiating to form a corresponding pattern on the etching object layer to a pattern of the resist layer.

15. A method of forming a wiring pattern, comprising:
forming a bank on the process object using the resist pattern formed on the process object using the method according to claim 1;
disposing a droplet including a wiring pattern forming material to form a wiring pattern on the process object.

16. A method of fabricating a semiconductor device, comprising:
forming a semiconductor device on the process object using the resist pattern formed on the process object using the method according to claim 1.

17. A method of forming a semiconductor device, comprising:
providing a resist layer including resist material on a base member including a photothermal conversion material to convert light energy into thermal energy;
facing the resist layer with an etching object layer of a process object;
irradiating a predetermined part of the base member with a light beam to transfer the resist material corresponding to the predetermined part to the etching object layer; and
etching the etching object layer to form a corresponding pattern on the etching object layer to the pattern of the resist layer.

18. An electro-optic device, comprising:
a wiring pattern formed by the wiring pattern forming method according to claim 15.

19. An electro-optic device, comprising:
a semiconductor device fabricated by the fabrication method according to claim 16.

20. An electronic apparatus, comprising:
the electro-optic device according to claim 18.
